(19) United States
(12) Patent Application Publication
(10) Pub. No.: US 2020/0199734 A1
(43) Pub. Date: Jun. 25, 2020

(54) MAGNESIUM ALLOY SURFACE COATING METHOD AND CORROSION-RESISTANT MAGNESIUM ALLOY PREPARED THEREBY

(71) Applicant: Kunshan Enijor Electronics Co., Ltd., Suzhou (CN)

(72) Inventors: Guixia Jiang, Suzhou (CN); Jianguo Jia, Suzhou (CN)

(21) Appl. No.: 16/722,240

(22) Filed: Dec. 20, 2019

(30) Foreign Application Priority Data
Dec. 21, 2018 (CN) 201811570475.9

(51) Int. Cl. C23C 14/06; C23C 14/02; C23C 14/34

(52) U.S. Cl. CPC C23C 14/0652; C23C 14/028; C23C 14/34; C23C 14/021

(57) ABSTRACT

The present invention discloses a magnesium alloy surface coating method and a corrosion-resistant magnesium alloy prepared thereby. The method includes the following steps: conducting pretreatment on a magnesium alloy substrate; depositing a metal film by sputtering on the surface of the pre-treated magnesium alloy substrate; and depositing a Si₃N₄ film by sputtering on the surface of the magnesium alloy substrate on which the metal film is deposited. The metal is any one of Nb, Cr, and Ta. The method in the present invention can provide effective protection for a magnesium alloy, thereby improving the corrosion resistance of the magnesium alloy.

### TECHNICAL FIELD

The present invention relates to a magnesium alloy surface coating method and a corrosion-resistant magnesium alloy prepared thereby, and belongs to the field of metal surface treatment technologies.

### BACKGROUND

As the lightest metal structural material, a magnesium alloy is known as a new generation of green engineering materials, but its application has been largely restricted due to its low corrosion resistance. Currently, one of the most effective methods to improve the corrosion resistance of the magnesium alloy is to form a protective film layer on its surface by using an appropriate surface treatment technology. Surface treatment technologies for protection of magnesium alloys mainly include a chemical conversion coating technique, vapor deposition, electrochemical plating, anodic oxidation, micro-arc oxidation, etc. Among them, the chemical conversion coating technique, electrochemical plating, anodic oxidation, micro-arc oxidation, etc. have such disadvantages as complex process and low coating-substrate adhesion, as well as high energy consumption and environmental pollution. In vapor deposition technologies, magnetron sputtering is a relatively important physical vapor deposition technique, and has such advantages as low deposition temperature, simple process, high film quality, and environmental friendliness. Therefore, it has become the main method for the industrial application of films. Some methods for surface modification of magnesium alloys by vapor deposition have been developed at home and abroad, to improve the corrosion resistance and wear resistance of the magnesium alloys. However, there still exist some shortcomings such as low coating-substrate adhesion, surface voids and cracks, and unsatisfactory corrosion resistance.

### SUMMARY

An objective of the present invention is to provide a magnesium alloy surface coating method, which can obtain a magnesium alloy with excellent corrosion resistance.

Another objective of the present invention is to provide a corrosion-resistant magnesium alloy that has excellent corrosion resistance.

To achieve the above objectives, the present invention provides a magnesium alloy surface coating method, including the following steps:

conducting pretreatment on a magnesium alloy substrate;

depositing a metal film by sputtering on the surface of the pre-treated magnesium alloy substrate; and

depositing a Si₃N₄ film by sputtering on the surface of the magnesium alloy substrate on which the metal film is deposited.

Further, the metal is any one of Nb, Cr, and Ta.

Further, a thickness of the metal film is 1 μm.

Further, a thickness of the Si₃N₄ film is 2 μm.

Further, the magnesium alloy surface coating method further includes: removing gas adsorbate on the surface of the magnesium alloy substrate by using an ion source before depositing the metal film.

Further, the magnesium alloy surface coating method further includes: holding the cavity temperature of a sputtering chamber at 100° C. and the temperature of the magnesium alloy substrate at 250° C. during deposition of Si₃N₄ film.

The present invention further provides a corrosion-resistant magnesium alloy, including a magnesium alloy substrate, a metal film deposited on the magnesium alloy substrate, and a Si₃N₄ film deposited on the metal film.

Further, the metal is any one of Nb, Cr, and Ta.

Further, a thickness of the metal film is 1 μm.

Further, a thickness of the Si₃N₄ film is 2 μm.

Compared with the prior art, the present invention has the following beneficial effects: The Si₃N₄ film of the present invention has a smooth and compact surface, and can serve as a protective outer layer to effectively reduce a corrosion rate of the magnesium alloy. In addition, a metal transition layer is first deposited by sputtering on the surface of the magnesium alloy, which can increase adhesion between the Si₃N₄ film and the magnesium alloy to achieve high coating-substrate adhesion. In this way, the magnesium alloy has excellent corrosion resistance. Moreover, passivation can occur at the Nb, Ta, or Cr transition layer to form a passive film, further improving the corrosion resistance of the magnesium alloy.

### DETAILED DESCRIPTION

The present invention is further described below with reference to specific embodiments. The following embodiments are only used for describing the technical solutions of the present invention more clearly, and are not intended to limit the protection scope of the present invention.

1. Film Preparation

In the embodiments of the present invention, AZ31 magnesium alloy is used as a substrate for deposition, and a device used is a K08030 cutting tool modified multi arc magnetron sputtering coating system (Shenyang Scientific Instrument Research Center, Chinese Academy of Sciences). Sputtering targets are 99.99% silicon and metals Nb, Ta, and Cr, and sputtering gases are argon gas and nitrogen gas.

### EMBODIMENT 1

The surface of a magnesium alloy substrate was ground and polished repeatedly until surface roughness was below 0.5 μm. The treated magnesium alloy substrate was placed in anhydrous ethanol for ultrasonic cleaning for 10 min, then placed in acetone for ultrasonic cleaning for 15 min, and dried.

The dried magnesium alloy substrate was fastened to a sample rotary table of a sputtering chamber; a vacuum system was started for vacuumizing until base pressure is 6×10⁻⁴ Pa, and heating was conducted to remove water vapor.

Argon gas was introduced, and a gas flow was adjusted to make gas pressure in the sputtering chamber reach 0.3 Pa. A Hall ion source was started, Ar⁺ was used to bombard the surface of the magnesium alloy substrate, so as to remove gas adsorbate on the surface of the substrate and improve adhesion of a deposited film on the substrate.

After removal of the gas adsorbate, an introduction amount of argon gas was adjusted to make the gas pressure in the sputtering chamber reach 1 Pa, where sputtering power was 150 W.

A power supply was turned on; direct current sputtering was conducted on the Nb target; and a sputtering time was controlled, so that the power supply was turned off after a thickness of a Nb film approximated 1 μm.

Nitrogen gas was introduced, and a total flow of argon gas and nitrogen gas was controlled to be 50 sccm (a flow of nitrogen gas accounted for approximately 10% of the total flow). Gas pressure in the sputtering chamber was 1 Pa; a bias voltage of the substrate was 0 V; and sputtering power was 250 W.

A cavity of the sputtering chamber was heated to 100° C.; the magnesium alloy substrate was heated to 250° C.; and the temperature was kept constant.

A power supply was turned on; radio frequency sputtering was conducted on the Si target; and a sputtering time was controlled, so that a thickness of a deposited Si₃N₄ film approximated 2 μm.

After deposition ends, the power supply was turned off, a nitrogen gas valve was closed, and the substrate with the Si₃N₄ film was cooled in an argon gas flow. After the temperature of the sputtering chamber was reduced to room temperature, the vacuum system was turned off. In this way, the magnesium alloy substrate plated with a Nb/Si₃N₄ composite film was obtained.

### EMBODIMENT 2

The surface of a magnesium alloy substrate was ground and polished repeatedly until surface roughness was below 0.5 μm. The treated magnesium alloy substrate was placed in anhydrous ethanol for ultrasonic cleaning for 10 min, then placed in acetone for ultrasonic cleaning for 15 min, and dried.

The dried magnesium alloy substrate was fastened to a sample rotary table of a sputtering chamber; a vacuum system was started for vacuumizing until base pressure is 6×10⁻⁴ Pa, and heating was conducted to remove water vapor.

Argon gas was introduced, and a gas flow was adjusted to make gas pressure in the sputtering chamber reach 0.3 Pa. A Hall ion source was started, Ar⁺ was used to bombard the surface of the magnesium alloy substrate, so as to remove gas adsorbate on the surface of the substrate and improve adhesion of a deposited film on the substrate.

After removal of the gas adsorbate, an introduction amount of Argon gas was adjusted to make the gas pressure in the sputtering chamber reach 1 Pa, where sputtering power was 150 W.

A power supply was turned on; direct current sputtering was conducted on the Cr target; and a sputtering time was controlled, so that the power supply was turned off after a thickness of a Cr film approximated 1 μm.

Nitrogen gas was introduced, and a total flow of argon gas and nitrogen gas was controlled to be 60 sccm (a flow of nitrogen gas accounted for approximately 15% of the total flow). Gas pressure in the sputtering chamber was 1 Pa; a bias voltage of the substrate was 0 V; and sputtering power was 250 W.

A cavity of the sputtering chamber was heated to 100° C.; the magnesium alloy substrate was heated to 250° C.; and the temperature was kept constant.

A power supply was turned on; radio frequency sputtering was conducted on the Si target; and a sputtering time was controlled, so that a thickness of a deposited Si₃N₄ film approximated 2 μm.

After deposition ends, the power supply was turned off, a nitrogen gas valve was closed, and the substrate with the Si₃N₄ film was cooled in an Argon gas flow. After the temperature of the sputtering chamber was reduced to room temperature, the vacuum system was turned off. In this way, the magnesium alloy substrate plated with a Cr/Si₃N₄ composite film was obtained.

### EMBODIMENT 3

The surface of a magnesium alloy substrate was ground and polished repeatedly until surface roughness was below 0.5 μm. The treated magnesium alloy substrate was placed in anhydrous ethanol for ultrasonic cleaning for 10 min, then placed in acetone for ultrasonic cleaning for 15 min, and dried.

The dried magnesium alloy substrate was fastened to a sample rotary table of a sputtering chamber; a vacuum system was started for vacuumizing until base pressure is 6×10⁻⁴ Pa, and heating was conducted to remove water vapor.

Argon gas was introduced, and a gas flow was adjusted to make gas pressure in the sputtering chamber reach 0.3 Pa. A Hall ion source was started, Ar⁺ was used to bombard the surface of the magnesium alloy substrate, so as to remove gas adsorbate on the surface of the substrate and improve adhesion of a deposited film on the substrate.

After removal of the gas adsorbate, an introduction amount of argon gas was adjusted to make the gas pressure in the sputtering chamber reach 1 Pa, where sputtering power was 150 W.

A power supply was turned on; direct current sputtering was conducted on the Ta target; and a sputtering time was controlled, so that the power supply was turned off after a thickness of a Ta film approximated 1 μm.

Nitrogen gas was introduced, and a total flow of argon gas and nitrogen gas was controlled to be 60 sccm (a flow of nitrogen gas accounted for approximately 15% of the total flow). Gas pressure in the sputtering chamber was 1 Pa; a bias voltage of the substrate was 0 V; and sputtering power was 250 W.

A cavity of the sputtering chamber was heated to 100° C.; the magnesium alloy substrate was heated to 250° C.; and the temperature was kept constant.

A power supply was turned on; radio frequency sputtering was conducted on the Si target; and a sputtering time was controlled, so that a thickness of a deposited Si₃N₄ film approximated 2 μm.

After deposition ends, the power supply was turned off, a nitrogen gas valve was closed, and the substrate with the Si₃N₄ film was cooled in an Argon gas flow. After the temperature of the sputtering chamber was reduced to room temperature, the vacuum system was turned off. In this way, the magnesium alloy substrate plated with a Ta/Si₃N₄ composite film was obtained.

2. Neutral Salt Spray Test

1. An uncoated magnesium alloy and the magnesium alloy substrate plated with Nb/Si₃N₄ were placed in a salt spray test chamber for one week. Results showed that the uncoated magnesium alloy was seriously corroded with a corrosion area greater than 50%, while the magnesium alloy substrate plated with Nb/Si₃N₄ was basically intact with a corrosion area of approximately 5%.

2. An uncoated magnesium alloy and the magnesium alloy substrate plated with Cr/Si₃N₄ were placed in a salt spray test chamber for one week. Results showed that the uncoated magnesium alloy was seriously corroded with a corrosion area greater than 50%, while the magnesium alloy substrate plated with Cr/Si₃N₄ was basically intact with a corrosion area of approximately 6%.

3. An uncoated magnesium alloy and the magnesium alloy substrate plated with Ta/Si₃N₄ were placed in a salt spray test chamber for 100 h. Results showed that the uncoated magnesium alloy was seriously corroded with a corrosion area greater than 50%, while the magnesium alloy substrate plated with Ta/Si₃N₄ was basically intact with a corrosion area of approximately 5%.

The above results showed that depositing the Nb/Si₃N₄, Cr/Si₃N₄, or Ta/Si₃N₄ composite film on the magnesium alloy can provide effective protection for the magnesium alloy, thereby improving the corrosion resistance of the magnesium alloy.

The present invention has been disclosed above by using the preferred embodiments, but this is not intended to limit the present invention. Any technical solution obtained by adopting equivalent replacement or equivalent transformation shall fall within the protection scope of the present invention.

What is claimed is:

1. A magnesium alloy surface coating method, comprising the following steps
conducting pretreatment on a magnesium alloy substrate;
depositing a metal film by sputtering on the surface of the pre-treated magnesium alloy substrate; and
depositing a Si₃N₄ film by sputtering on the surface of the magnesium alloy substrate on which the metal film is deposited.

2. The magnesium alloy surface coating method according to claim 1, wherein the metal is any one of Nb, Cr, and Ta.

3. The magnesium alloy surface coating method according to claim 1, wherein a thickness of the metal film is 1 μm.

4. The magnesium alloy surface coating method according to claim 1, wherein a thickness of the Si₃N₄ film is 2 μm.

5. The magnesium alloy surface coating method according to claim 1, wherein the method further comprises: removing gas adsorbate on the surface of the magnesium alloy substrate by using an ion source before depositing the metal film.

6. The magnesium alloy surface coating method according to claim 1, wherein the method further comprises: holding the cavity temperature of a sputtering chamber at 100° C. and the temperature of the magnesium alloy substrate at 250° C. during deposition of the Si₃N₄ film.

7. A corrosion-resistant magnesium alloy, comprising a magnesium alloy substrate, a metal film deposited on the magnesium alloy substrate, and a Si₃N₄ film deposited on the metal film.

8. The corrosion-resistant magnesium alloy according to claim 7, wherein the metal is any one of Nb, Cr, and Ta.

9. The corrosion-resistant magnesium alloy according to claim 7, wherein a thickness of the metal film is 1 μm.

10. The corrosion-resistant magnesium alloy according to claim 7, wherein a thickness of the Si₃N₄ film is 2 μm.
